(19) United States
(12) Patent Application Publication
(10) Pub. No.: US 2023/0157133 A1
(43) Pub. Date: May 18, 2023

(54) OLED DISPLAY SUBSTRATE, MANUFACTURING METHOD THEREOF AND DISPLAY DEVICE

(71) Applicant: BOE Technology Group Co., Ltd., Beijing (CN)

(72) Inventors: Guoying WANG, Beijing (CN); Zhen SONG, Beijing (CN)

(21) Appl. No.: 17/425,563

(22) PCT Filed: Feb. 24, 2021
(86) PCT No.: PCT/CN2021/077623

§ 371 Date: Jul. 23, 2021

(30) Foreign Application Priority Data
Feb. 25, 2020 (CN) 202010116298.8

(51) Int. Cl. H10K 59/80; H10K 59/12; H10K 59/122

(52) U.S. Cl. CPC H10K 59/80522; H10K 59/1201; H10K 59/122

(57) ABSTRACT

The present disclosure provides an OLED display substrate, a manufacturing method thereof, and a display device. The manufacturing method includes: forming a driving circuitry layer and a first electrode of a light-emitting element on a base substrate; forming a protection layer covering the first electrode; forming a plurality of auxiliary electrode structures, at least one side surface of each auxiliary electrode structure being provided with a notch for exposing a conductive portion of the auxiliary electrode structure; removing at least a part of the protection layer covering the first electrode to expose the first electrode; forming a light-emitting layer of the light-emitting element, the light-emitting layer being interrupted at the notch to expose the side surface of the auxiliary electrode structure; and forming a second electrode of the light-emitting element, the second electrode being electrically coupled to the conductive portion at the side surface of the auxiliary electrode structure.

### CROSS-REFERENCE TO RELATED APPLICATIONS

The present application claims a priority of the Chinese Patent Application No. 202010116298.8 filed on Feb. 25, 2020, which is incorporated herein by reference in its entirety.

### TECHNICAL FIELD

The present disclosure relates to the field of display technology, in particular to an Organic Light-Emitting Diode (OLED) display substrate, a manufacturing method thereof, and a display device.

### BACKGROUND

OLED display device has become the next-generation display device with great competitiveness and a development prospect due to such advantages as self-luminescence, fast response, high brightness, a full viewing angle and flexible display.

The OLED display device includes a bottom-emission structure and a top-emission structure. The top-emission OLED display device is currently a hot-spot in the display technology because the top-emission structure can significantly increase an aperture ratio of the OLED display device and increase pixels per inch (PPI).

However, a cathode of the top-emission OLED display device is made of a transparent or semi-transparent conductive material and has a small thickness, so a resistance of the cathode is relatively high. At this time, a serious voltage drop (IR-drop) occurs when the display device is being driven, and thereby uniformity of the display brightness of the OLED display device is adversely affected.

### SUMMARY

An object of the present disclosure is to provide an OLED display substrate, a manufacturing method thereof, and a display device, so as to prevent the occurrence of the IR-drop due to a too large resistance of the cathode.

In order to solve the above technical problem, the present disclosure provides in the embodiments the following technical solutions.

In one aspect, the present disclosure provides in some embodiments a method for manufacturing an OLED display substrate, including: forming a driving circuitry layer and a first electrode of a light-emitting element on a base substrate; forming a protection layer covering the first electrode; forming a plurality of auxiliary electrode structures, at least one side surface of each auxiliary electrode structure being provided with a notch for exposing a conductive portion of the auxiliary electrode structure; removing at least a part of the protection layer covering the first electrode to expose the first electrode; forming a light-emitting layer of the light-emitting element, the light-emitting layer being interrupted at the notch to expose the side surface of the auxiliary electrode structure; and forming a second electrode of the light-emitting element, the second electrode being electrically coupled to the conductive portion at the side surface of the auxiliary electrode structure.

In a possible embodiment of the present disclosure, the forming the protection layer includes depositing an inorganic insulating layer to form the protection layer.

In a possible embodiment of the present disclosure, the protection layer has a thickness of 500 angstroms to 1000 angstroms.

In a possible embodiment of the present disclosure, the forming the plurality of auxiliary electrode structures includes: forming a plurality of auxiliary electrode transition structures, each auxiliary electrode transition structure including a metal pattern and an insulation pattern laminated one on another, the insulation pattern being located at a side of the metal pattern away from the base substrate; and dry-etching the insulation pattern and wet-etching the metal pattern to form the auxiliary electrode structure with the notch in the side surface. A first orthogonal projection of the metal pattern onto the base substrate is located in a second orthogonal projection of the insulation pattern onto the base substrate, and an area of the first orthogonal projection is smaller than an area of the second orthogonal projection.

In a possible embodiment of the present disclosure, the forming the plurality of auxiliary electrode structures includes: forming a plurality of auxiliary electrode transition structures, each auxiliary electrode transition structure including a first conductive pattern and a second conductive pattern laminated one on another, the second conductive pattern being located at a side of the first conductive pattern away from the base substrate, and an etchant for the first conductive pattern being different from an etchant for the second conductive pattern; and wet-etching the second conductive pattern and the first conductive pattern sequentially using different etchants to form the auxiliary electrode structure with the notch in the side surface. A third orthogonal projection of the first conductive pattern onto the base substrate is located in a fourth orthogonal projection of the second conductive pattern onto the base substrate, and an area of the third orthogonal projection is smaller than an area of the fourth orthogonal projection.

In a possible embodiment of the present disclosure, subsequent to forming the auxiliary electrode transition structure and prior to forming the auxiliary electrode structure, the method further includes: forming a pattern of a pixel definition layer; and etching a film layer of the auxiliary electrode transition structure with the pattern of the pixel definition layer as a mask, to form the auxiliary electrode structure.

In a possible embodiment of the present disclosure, the removing the at least a part of the protection layer covering the first electrode to expose the first electrode includes patterning the pixel definition layer to form the pattern of the pixel definition layer. A plurality of pixel apertures is defined by the pattern of the pixel definition layer to expose the first electrode.

In a possible embodiment of the present disclosure, at least a part of the protection layer covering the first electrode is removed through dry-etching to expose the first electrode.

In another aspect, the present disclosure provides in some embodiments an OLED display substrate manufactured through the above-mentioned manufacturing method and including a light-emitting region and a non-light-emitting region. The OLED display substrate includes: a planarization layer and a driving circuitry layer arranged on a base substrate; a first electrode of a light-emitting element arranged at the light-emitting region and an auxiliary electrode structure arranged at the non-light-emitting region, at least one side surface of the auxiliary electrode structure being provided with a notch for exposing a conductive portion of the auxiliary electrode structure; a light-emitting layer of the light-emitting element, the light-emitting layer being interrupted at the notch; and a second electrode electrically coupled to the conductive portion at the side surface of the auxiliary electrode structure.

In a possible embodiment of the present disclosure, the OLED display substrate further includes a protection layer covering the first electrode.

In a possible embodiment of the present disclosure, the protection layer has a thickness of 500 angstroms to 1000 angstroms.

In a possible embodiment of the present disclosure, the OLED display substrate further includes a pixel definition layer arranged at a side of the first electrode and a side of the auxiliary electrode structure away from the base substrate/The pixel definition layer is located at the non-light-emitting region and provided with a first hollowed-out region at the non-light-emitting region so as to expose the side surface of the auxiliary electrode structure.

In a possible embodiment of the present disclosure, the OLED display substrate further includes a pixel definition layer arranged at the non-light-emitting region, and the auxiliary electrode structure is arranged at a side of the pixel definition layer away from the base substrate.

In yet another aspect, the present disclosure provides in some embodiments an OLED display device including the above-mentioned OLED display substrate and an encapsulation layer for encapsulating the OLED display substrate.

### BRIEF DESCRIPTION OF THE DRAWINGS

FIGS. 1-8 are schematic views showing the manufacture of an OLED display substrate according to one embodiment of the present disclosure; and

FIGS. 9-12 are schematic views showing the manufacture of the OLED display substrate according to another embodiment of the present disclosure.

### REFERENCE NUMERALS

1 substrate
2 first electrode
3 protection layer
4 first film layer
5 second film layer
6 pixel definition layer
7 light-emitting layer
8 second electrode

### DETAILED DESCRIPTION

In order to make the objects, the technical solutions and the advantages of the present disclosure more apparent, the present disclosure will be described hereinafter in a clear and complete manner in conjunction with the drawings and embodiments.

In order to prevent the occurrence of an IR-drop due to a too large resistance of a cathode, an auxiliary electrode structure coupled in parallel to the cathode is formed on an OLED display substrate. However, during the formation of the auxiliary electrode structure, an anode (which is usually made of Indium Tin Oxide (ITO)) is damaged to some extent due to H ions in an etchant for a metal, and thereby a yield of the OLED display substrate is adversely affected.

An object of the present disclosure is to provide an OLED display substrate, a manufacturing method thereof, and a display device, so as to prevent the occurrence of an IR-drop due to a too large resistance of a cathode and improve the yield of the OLED display substrate.

The present disclosure provides in some embodiments a method for manufacturing an OLED display substrate, which includes: forming a planarization layer, a driving circuitry layer and a first electrode of a light-emitting element on a base substrate; forming a protection layer covering the first electrode; forming a plurality of auxiliary electrode structures, at least one side surface of each auxiliary electrode structure being provided with a notch for exposing a conductive portion of the auxiliary electrode structure; removing at least a part of the protection layer covering the first electrode to expose the first electrode; forming a light-emitting layer of a light-emitting element, the light-emitting layer being interrupted at the notch to expose the side surface of the auxiliary electrode structure; and forming a second electrode of the light-emitting element, the second electrode being electrically coupled to the conductive portion at the side surface of the auxiliary electrode structure.

According to the embodiments of the present disclosure, the OLED display substrate includes the plurality of auxiliary electrode structures coupled in parallel to the second electrode, so as to reduce a resistance of the second electrode, thereby to prevent the occurrence of an IR-drop due to the relatively large resistance of the second electrode. When the OLED display substrate is applied to an OLED display device, it is able to ensure the uniformity of such characteristics of the OLED display device as display brightness, and improve the display quality of the OLED display device. In addition, before the formation of the auxiliary electrode structure, the protection layer always covers the first electrode, so as to protect the first electrode and prevent the first electrode from being damaged during the formation of the auxiliary electrode structure, thereby to improve a yield of the OLED display substrate.

In a possible embodiment of the present disclosure, the forming the protection layer includes depositing an inorganic insulating layer to form the protection layer. Usually, the inorganic insulating layer is made of a transparent material. As compared with the protection layer made of metal, when the protection layer is the inorganic insulating layer, it is able to prevent an aperture ratio of the OLED display substrate from being adversely affected.

The protection layer mainly functions as to protect the first electrode from being damaged, and after the formation of the auxiliary electrode structure, the protection layer covering the first electrode needs to be removed. In order to facilitate the removal of the protection layer and prevent a thickness of the OLED display substrate from being adversely affected by the protection layer to a great extent, a thickness of the protection layer should not be too large, e.g., the protection layer has a thickness of 500 angstroms to 1000 angstroms.

In a possible embodiment of the present disclosure, the forming the auxiliary electrode structure includes: forming a plurality of auxiliary electrode transition structures, each auxiliary electrode transition structure including a metal pattern and an insulation pattern laminated one on another, the insulation pattern being located at a side of the metal pattern away from the base substrate; and dry-etching the insulation pattern and wet-etching the metal pattern to form the auxiliary electrode structure with the notch in the side surface. A first orthogonal projection of the metal pattern onto the base substrate is located in a second orthogonal projection of the insulation pattern onto the base substrate, and an area of the first orthogonal projection is smaller than an area of the second orthogonal projection.

In another possible embodiment of the present disclosure, the forming the auxiliary electrode structure includes: forming a plurality of auxiliary electrode transition structures, each auxiliary electrode transition structure including a first conductive pattern and a second conductive pattern laminated one on another, the second conductive pattern being located at a side of the first conductive pattern away from the base substrate, and an etchant for the first conductive pattern being different from an etchant for the second conductive pattern; and wet-etching the second conductive pattern and the first conductive pattern sequentially using different etchants to form the auxiliary electrode structure with the notch in the side surface. A third orthogonal projection of the first conductive pattern onto the base substrate is located in a fourth orthogonal projection of the second conductive pattern onto the base substrate, and an area of the third orthogonal projection is smaller than an area of the fourth orthogonal projection.

In the embodiments of the present disclosure, subsequent to forming the auxiliary electrode transition structure and prior to forming the auxiliary electrode structure, the method further includes: forming a pattern of a pixel definition layer; and etching a film layer of the auxiliary electrode transition structure with the pattern of the pixel definition layer as a mask, to form the auxiliary electrode structure.

In this way, it is able to directly etch the film layer of the auxiliary electrode transition structure with the pattern of the pixel definition layer as a mask, thereby to reduce the quantity of process steps as well as the manufacture cost.

In a possible embodiment of the present disclosure, the removing the at least a part of the protection layer covering the first electrode to expose the first electrode includes patterning the pixel definition layer to form the pattern of the pixel definition layer. A plurality of pixel apertures is defined by the pattern of the pixel definition layer to expose the first electrode.

In a possible embodiment of the present disclosure, at least a part of the protection layer covering the first electrode is removed through dry-etching to expose the first electrode.

The technical solutions of the present disclosure will be further described hereinafter in conjunction with the drawings and the embodiments.

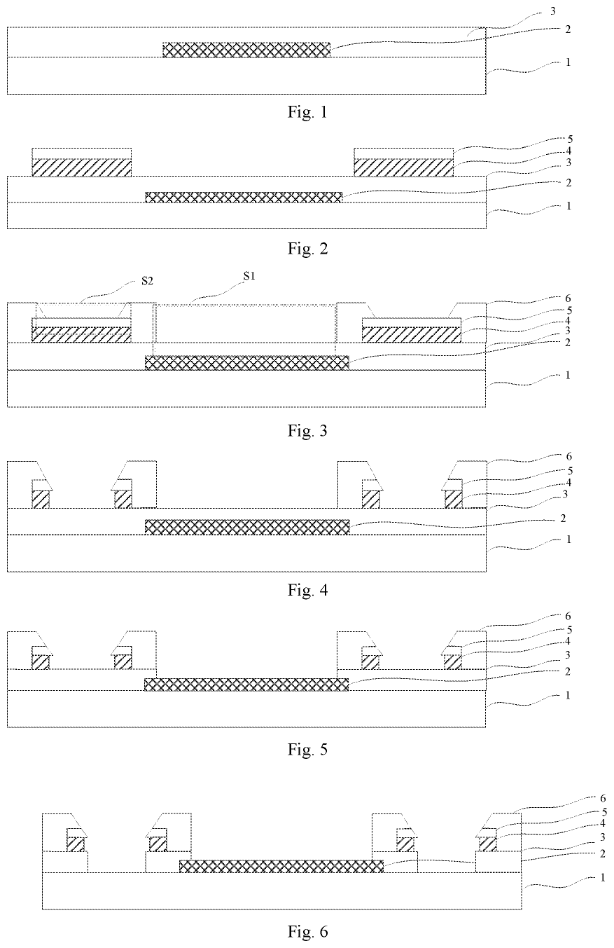

In a possible embodiment of the present disclosure, as shown in FIGS. 1-8, the method for manufacturing the OLED display substrate includes the following steps.

Step 1: as shown in FIG. 1, a first electrode 2 is formed on a substrate 1, and a protection layer 3 covering the first electrode 2 is formed.

The substrate 1 includes a base substrate and such film layers a planarization layer and a driving circuitry layer on the base substrate.

The first electrode 2 is an anode of the OLED display substrate, and it is made of a transparent conductive material such as ITO.

After the formation of the first electrode 2, an inorganic insulating layer made of SiOx or SiNx is deposited as the protection layer 3, and the protection layer 3 has a thickness of 1000 Å-1500 Å.

Step 2: as shown in FIG. 2, the auxiliary electrode transition structure is formed on the substrate 1 acquired after step 1, and the auxiliary electrode transition structure includes a first film layer 4 and a second film layer 5 laminated one on another.

The first film layer 4 is made of metal, and the second film layer 5 is made of an inorganic insulating material such as SiOx or SiNx. Alternatively, the first film layer 4 is made of metal and the second film layer 5 is made of a transparent conductive material. When the first film layer 4 is made of metal, the first film layer 4 is a metal layer made of Mo, AlNd, Al, and etc., or a lamination structure such as Mo/AlNd, Mo/AlNd/Mo, Mo/Al/Mo, AlNd/Mo, and etc.

Step 3: as shown in FIG. 3, a pattern of a pixel definition layer 6 is formed.

A pixel aperture region 51 and a light-emitting layer interruption region S2 are defined by the pattern of the pixel definition layer 6.

Step 4: as shown in FIG. 4, the auxiliary electrode transition structure is etched with the pattern of the pixel definition layer 6 as a mask to form an auxiliary electrode structure.

When the first film layer 4 is made of metal and the second film layer 5 is made of the inorganic insulating material SiOx or SiNx, the second film layer 5 is dry-etched, and then the first film layer 4 is wet-etched, so that an orthogonal projection of the first film layer 4 onto the substrate 1 is located within an orthogonal projection of the second film layer 5 onto the substrate 1. The first film layer 4 is retracted by a certain distance relative to the second film layer 5, so as to form the auxiliary electrode structure with a notch in a side surface.

When the first film layer 4 is made of metal and the second film layer 5 is made of a transparent conductive material, the second film layer 5 is wet-etched using an ITO etchant, and then the first film layer 4 is wet-etched using a metal etchant, so that the orthogonal projection of the first film layer 4 onto the substrate 1 is located within the orthogonal projection of the second film layer 5 onto the substrate 1. The first film layer 4 is retracted by a certain distance relative to the second film layer 5, so as to form the auxiliary electrode structure with the notch in the side surface.

Step 5: as shown in FIG. 5, the protection layer 3 covering the first electrode 2 is removed.

Specifically, the protection layer 3 at the pixel aperture region 51 is etched with the pattern of the pixel definition layer 6 as a mask, so as to remove the protection layer 3 covering the first electrode 2, thereby to expose the first electrode 2.

The protection layer 3 at the light-emitting layer interruption region S2 is also removed while removing the protection layer 3 at the pixel aperture region 51, as shown in FIG. 6. Of course, the protection layer 3 at the light-emitting layer interruption region S2 is reserved, as shown in FIG. 5.

A thickness of the protection layer 3 is greater than a thickness of the second film layer 5. In this way, when dry-etching the second film layer 5 and the protection layer 3 at the pixel aperture region 51 is also etched, the thickness of the protection layer 3 is reduced, but the first electrode 2 is protected by the remaining protection layer 3.

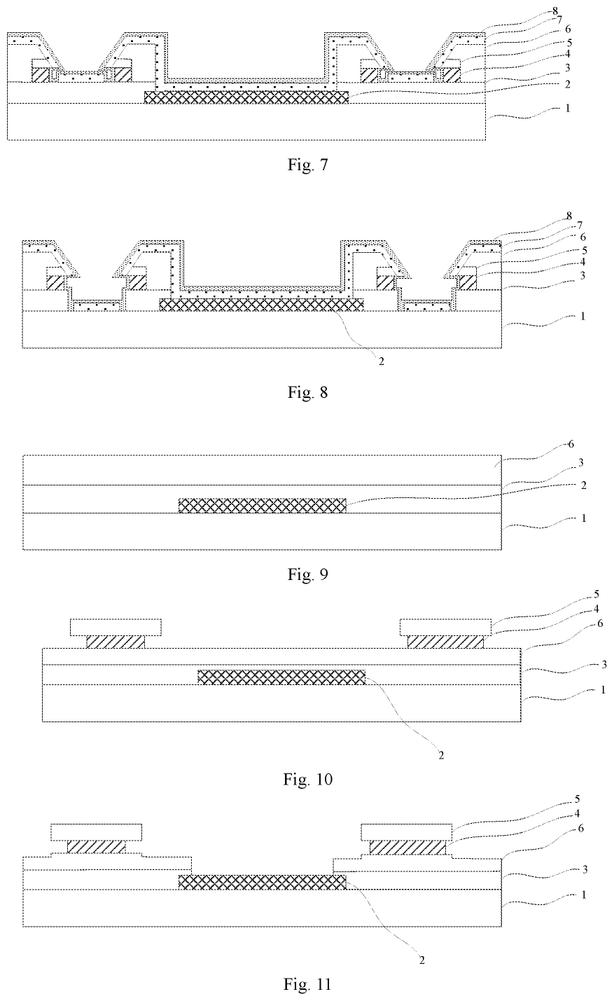

Step 6: as shown in FIGS. 7 and 8, a light-emitting layer 7 and a second electrode 8 are formed on the substrate 1 acquired after Step 5.

The light-emitting layer 7 is formed through evaporation. As shown in FIG. 7, the protection layer 3 at the light-emitting layer interruption region S2 is reserved, and the light-emitting layer 7 is interrupted at the notch so as to expose the side surface of the auxiliary electrode structure. Then, the second electrode 8 is formed, and the second electrode 8 is in contact with the side surface of the first film layer 4 of the auxiliary electrode structure at the notch. Because the first film layer 4 is made of a metal material, the second electrode 8 is electrically coupled to the auxiliary electrode structure, so that the second electrode 8 is coupled in parallel to the auxiliary electrode structure.

The light-emitting layer 7 is formed through evaporation. As shown in FIG. 8, the protection layer at the light-emitting layer interruption region S2 is removed, and the light-emitting layer 7 is interrupted at the notch so as to expose the side surface of the auxiliary electrode structure. Then, the second electrode 8 is formed, and the second electrode 8 is in contact with the side surface of the first film layer 4 of the auxiliary electrode structure at the notch. Because the first film layer 4 is made of a metal material, the second electrode 8 is electrically coupled to the auxiliary electrode structure, so that the second electrode 8 is coupled in parallel to the auxiliary electrode structure.

The second electrode 8 is a cathode, and it is usually made of reflective metal.

In another possible embodiment of the present disclosure, as shown in FIGS. 9-12, the method for manufacturing the OLED display substrate includes the following steps.

Step 1: as shown in FIG. 9, the first electrode 2 is formed on the substrate 1, and the protection layer 3 covering the first electrode 2 and the pixel definition layer 6 are formed.

The substrate 1 includes a base substrate and such film layers as a planarization layer and a driving circuitry layer located on the base substrate.

The first electrode 2 is an anode of the OLED display substrate, and made of a transparent conductive material such as ITO.

After the formation of the first electrode 2, an inorganic insulating layer made of SiOx or SiNx is deposited as the protection layer 3, and the protection layer 3 has a thickness of 1000 Å-1500 Å.

In a possible embodiment of the present disclosure, the protection layer 3 is omitted, and the pixel definition layer 6 is directly used as the protection layer, so as to simplify the structure of the OLED display substrate.

Step 2: as shown in FIG. 10, the auxiliary electrode transition structure is formed on the substrate 1 acquired after Step 1. The auxiliary electrode transition structure includes the first film layer 4 and the second film layer 5 laminated one on another.

The first film layer 4 is made of metal, and the second film layer 5 is made of an inorganic insulating material such as SiOx or SiNx. Alternatively, the first film layer 4 is made of metal and the second film layer 5 is made of a transparent conductive material. When the first film layer 4 is made of metal, the first film layer 4 is a metal layer made of Mo, AlNd, Al, and etc., or a lamination structure such as Mo/AlNd, Mo/AlNd/Mo, Mo/Al/Mo, AlNd/Mo, and etc.

When the first film layer 4 is made of metal and the second film layer 5 is made of the inorganic insulating material SiOx or SiNx, the second film layer 5 is dry-etched, and then the first film layer 4 is wet-etched, so that an orthogonal projection of the first film layer 4 onto the substrate 1 is located within an orthogonal projection of the second film layer 5 onto the substrate 1. The first film layer 4 is retracted by a certain distance relative to the second film layer 5, so as to form the auxiliary electrode structure with a notch in a side surface.

When the first film layer 4 is made of metal and the second film layer 5 is made of a transparent conductive material, the second film layer 5 is wet-etched using an ITO etchant, and then the first film layer 4 is wet-etched using a metal etchant, so that the orthogonal projection of the first film layer 4 onto the substrate 1 is located within the orthogonal projection of the second film layer 5 onto the substrate 1. The first film layer 4 is retracted by a certain distance relative to the second film layer 5, so as to form the auxiliary electrode structure with the notch in the side surface.

Step 3: as shown in FIG. 11, the pixel definition layer 6 and the protection layer 3 are patterned, the pixel definition layer 6 and the protection layer 3 covering the first electrode 2 are removed to form a pattern of the pixel definition layer 6 and a pattern of the protection layer 3.

When patterning the pixel definition layer 6 and the protection layer 3, the pixel definition layer 6 not covered by the auxiliary electrode structure is etched, and steps are formed at both sides of the pattern of the pixel definition layer 6. The pixel aperture region is defined by the pattern of the pixel definition layer 6 and the pattern of the protection layer 3.

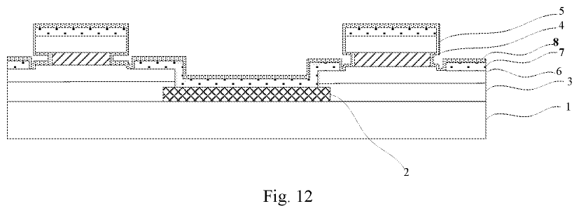

Step 4: as shown in FIG. 12, the light-emitting layer 7 and the second electrode 8 are formed on the substrate 1 acquired after Step 3.

The light-emitting layer 7 is formed through evaporation. As shown in FIG. 12, the light-emitting layer 7 is interrupted at the notch so as to expose the side surface of the auxiliary electrode structure. Then, the second electrode 8 is formed, and the second electrode 8 is in contact with the side surface of the first film layer 4 of the auxiliary electrode structure at the notch. Because the first film layer 4 is made of a metal material, the second electrode 8 is electrically coupled to the auxiliary electrode structure, so that the second electrode 8 is coupled in parallel to the auxiliary electrode structure.

The second electrode 8 is a cathode, and usually it is made of reflective metal.

The present disclosure further provides in some embodiments an OLED display substrate manufactured through the above-mentioned manufacturing method and including a light-emitting region and a non-light-emitting region. The OLED display substrate includes: a planarization layer and a driving circuitry layer arranged on a base substrate; a first electrode of a light-emitting element arranged at the light-emitting region and an auxiliary electrode structure arranged at the non-light-emitting region, at least one side surface of the auxiliary electrode structure being provided with a notch for exposing a conductive portion of the auxiliary electrode structure; a light-emitting layer of the light-emitting element, the light-emitting layer being interrupted at the notch; and a second electrode electrically coupled to the conductive portion at the side surface of the auxiliary electrode structure.

In a possible embodiment of the present disclosure, the OLED display substrate further includes a protection layer covering the first electrode.

In a possible embodiment of the present disclosure, the protection layer has a thickness of 500 angstroms to 1000 angstroms.

In a possible embodiment of the present disclosure, the OLED display substrate includes a plurality of auxiliary electrode structures coupled to the second electrode. The plurality of auxiliary electrode structure is coupled in parallel to the second electrode, so as to reduce a resistance of the second electrode, thereby to prevent the occurrence of an IR-drop due to the relatively large resistance of the second electrode. When the OLED display substrate is applied to an OLED display device, it is able to ensure the uniformity of such characteristics of the OLED display device as the display brightness, and improve the display quality of the OLED display device. In addition, before the formation of the auxiliary electrode structure, the protection layer always covers the first electrode, so as to protect the first electrode and prevent the first electrode from being damaged during the formation of the auxiliary electrode structure, thereby to improve a yield of the OLED display substrate.

The OLED display substrate further includes a pixel definition layer arranged at a side of the first electrode and a side of the auxiliary electrode structure away from the base substrate. The pixel definition layer is located at the non-light-emitting region and provided with a first hollowed-out region at the non-light-emitting region so as to expose the side surface of the auxiliary electrode structure. In this way, it is able for the second electrode to be electrically coupled to the auxiliary electrode structure via the first hollowed-out region.

In a possible embodiment of the present disclosure, the OLED display substrate further includes a pixel definition layer arranged at the non-light-emitting region, and the auxiliary electrode structure is arranged at a side of the pixel definition layer away from the base substrate.

In this way, during the manufacture of the OLED display substrate, the first electrode of the OLED display substrate is protected by the pixel definition layer, and the pixel definition layer also serves as the first electrode of the OLED display substrate, so it is able to simplify the structure of the OLED display substrate and reduce the manufacture cost.

The present disclosure further provides in some embodiments an OLED display device including the above-mentioned OLED display substrate and an encapsulation layer for encapsulating the OLED display substrate.

The display device includes, but not limited to, a radio frequency unit, a network module, an audio output unit, an input unit, a sensor, a display unit, a user input unit, an interface unit, a memory, a processor, a power supply, etc. It should be appreciated that, the structure of the display device is not limited thereto, i.e., it includes more or fewer members, or some members are combined, or the members are arranged in different modes. In the embodiments of the present disclosure, the display device includes, but not limited to, display, mobile phone, tablet computer, television, wearable electronic device or navigator.

The display device is any product or member having a display function, such as television, display, digital photo frame, mobile phone and tablet computer. The display device further includes a flexible circuit board, a printed circuit board and a back plate.

In the embodiments of the present disclosure, the order of the steps is not limited to the serial numbers thereof. For a person skilled in the art, any change in the order of the steps shall also fall within the scope of the present disclosure if without any creative effort.

It should be further appreciated that, the above embodiments have been described in a progressive manner, and the same or similar contents in the embodiments have not been repeated, i.e., each embodiment has merely focused on the difference from the others. Especially, the product embodiments are substantially similar to the method embodiments, and thus have been described in a simple manner.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

It should be appreciated that, in the case that such an element as layer, film, region or substrate is arranged “on” or “under” another element, it may be directly arranged “on” or “under” the other element, or an intermediate element may be arranged therebetween.

In the above description, the features, structures, materials or characteristics may be combined in any embodiment or embodiments in an appropriate manner.

The above embodiments are for illustrative purposes only, but the present disclosure is not limited thereto. Obviously, a person skilled in the art may make further modifications and improvements without departing from the spirit of the present disclosure, and these modifications and improvements shall also fall within the scope of the present disclosure.

1. A method for manufacturing an Organic Light-Emitting Diode (OLED) display substrate, comprising:
forming a planarization layer, a driving circuitry layer and a first electrode of a light-emitting element on a base substrate;
forming a protection layer covering the first electrode;
forming a plurality of auxiliary electrode structures, at least one side surface of each auxiliary electrode structure being provided with a notch for exposing a conductive portion of the auxiliary electrode structure;
removing at least a part of the protection layer covering the first electrode to expose the first electrode;
forming a light-emitting layer of the light-emitting element, the light-emitting layer being interrupted at the notch to expose the side surface of the auxiliary electrode structure; and
forming a second electrode of the light-emitting element, the second electrode being electrically coupled to the conductive portion at the side surface of the auxiliary electrode structure.

2. The method according to claim 1, wherein the forming the protection layer comprises depositing an inorganic insulating layer to form the protection layer.

3. The method according to claim 1, wherein the protection layer has a thickness of 500 angstroms to 1000 angstroms.

4. The method according to claim 1, wherein the forming the plurality of auxiliary electrode structures comprises:
forming a plurality of auxiliary electrode transition structures, each auxiliary electrode transition structure comprising a metal pattern and an insulation pattern laminated one on another, the insulation pattern being located at a side of the metal pattern away from the base substrate; and
dry-etching the insulation pattern and wet-etching the metal pattern to form the auxiliary electrode structure with the notch in the side surface,
wherein a first orthogonal projection of the metal pattern onto the base substrate is located in a second orthogonal projection of the insulation pattern onto the base substrate, and an area of the first orthogonal projection is smaller than an area of the second orthogonal projection.

5. The method according to claim 1, wherein the forming the plurality of auxiliary electrode structures comprises:
forming a plurality of auxiliary electrode transition structures, each auxiliary electrode transition structure comprising a first conductive pattern and a second conductive pattern laminated one on another, the second conductive pattern being located at a side of the first conductive pattern away from the base substrate, and an etchant for the first conductive pattern being different from an etchant for the second conductive pattern; and
wet-etching the second conductive pattern and the first conductive pattern sequentially using different etchants to form the auxiliary electrode structure with the notch in the side surface,
wherein a third orthogonal projection of the first conductive pattern onto the base substrate is located in a fourth orthogonal projection of the second conductive pattern onto the base substrate, and an area of the third orthogonal projection is smaller than an area of the fourth orthogonal projection.

6. The method according to claim 4, wherein subsequent to forming the auxiliary electrode transition structure and prior to forming the auxiliary electrode structure, the method further comprises:
forming a pattern of a pixel definition layer; and
etching a film layer of the auxiliary electrode transition structure with the pattern of the pixel definition layer as a mask, to form the auxiliary electrode structure.

7. The method according to claim 6, wherein the removing the at least a part of the protection layer covering the first electrode to expose the first electrode comprises patterning the pixel definition layer to form the pattern of the pixel definition layer, and a plurality of pixel apertures is defined by the pattern of the pixel definition layer to expose the first electrode.

8. The method o according to claim 1, wherein at least a part of the protection layer covering the first electrode is removed through dry-etching to expose the first electrode.

9. An OLED display substrate manufactured through the method according to claim 1, and comprising a light-emitting region and a non-light-emitting region, wherein the OLED display substrate comprises:
a planarization layer and a driving circuitry layer arranged on a base substrate;
a first electrode of a light-emitting element arranged at the light-emitting region and an auxiliary electrode structure arranged at the non-light-emitting region, at least one side surface of the auxiliary electrode structure being provided with a notch for exposing a conductive portion of the auxiliary electrode structure;
a light-emitting layer of the light-emitting element, the light-emitting layer being interrupted at the notch; and
a second electrode electrically coupled to the conductive portion at the side surface of the auxiliary electrode structure.

10. The OLED display substrate according to claim 9, further comprising a protection layer covering the first electrode.

11. The OLED display substrate according to claim 10, wherein the protection layer has a thickness of 500 angstroms to 1000 angstroms.

12. The OLED display substrate according to claim 9, further comprising a pixel definition layer arranged at a side of the first electrode and a side of the auxiliary electrode structure away from the base substrate, wherein the pixel definition layer is located at the non-light-emitting region and provided with a first hollowed-out region at the non-light-emitting region so as to expose the side surface of the auxiliary electrode structure.

13. The OLED display substrate according to claim 9, further comprising a pixel definition layer arranged at the non-light-emitting region, wherein the auxiliary electrode structure is arranged at a side of the pixel definition layer away from the base substrate.

14. An OLED display device comprising the OLED display substrate according to claim 9 and an encapsulation layer for encapsulating the OLED display substrate.

15. The method according to claim 2, wherein the protection layer has a thickness of 500 angstroms to 1000 angstroms.

16. The method according to claim 5, wherein subsequent to forming the auxiliary electrode transition structure and prior to forming the auxiliary electrode structure, the method further comprises:
forming a pattern of a pixel definition layer; and
etching a film layer of the auxiliary electrode transition structure with the pattern of the pixel definition layer as a mask, to form the auxiliary electrode structure.
